(19) United States
(12) Patent Application Publication
(10) Pub. No.: US 2009/0248333 A1
(43) Pub. Date: Oct. 1, 2009

(54) RECHARGEABLE "SMART" BATTERY WITH CYCLE STATUS INDICATOR FOR USE IN MOBILE, HANDHELD ELECTRICAL DEVICES

(76) Inventors: Michael E. Grosberg, Sudbury, MA (US); Danny Rockett, Palm Beach Garden, FL (US)

Correspondence Address: Mark J. Pandiscio;Pandiscio & Pandiscio, P.C., 470 Totten Pond Road, Waltham, MA, 02451, US

(21) Appl. No.: 12/272,429

(22) Filed: Nov. 17, 2008

Related U.S. Application Data
(60) Provisional application No. 61/003,327, filed on Nov. 16, 2007.

(51) Int. Cl. G01R 31/36

(52) U.S. Cl. 702/63

(57) ABSTRACT

An electronic battery label for displaying the status of a “smart” battery, wherein the “smart” battery comprises “smart” circuitry for determining the status of the “smart” battery, the electronic battery label comprising:
an e-paper display;
means for mounting the e-paper display to the “smart” battery; and
connection means for electrically connecting the e-paper display to the “smart” circuitry of the “smart” battery.

A “smart” battery assembly comprising:
a “smart” battery comprising “smart” circuitry for determining the status of the “smart” battery; and
an electronic battery label for displaying the status of a “smart” battery, wherein the electronic battery label comprises:
   an e-paper display;
   means for mounting the e-paper display to the “smart” battery; and
   connection means for electrically connecting the e-paper display to the “smart” circuitry of the “smart” battery.

A method for displaying the status of a battery, the method comprising:
providing a “smart” battery assembly comprising:
   a “smart” battery comprising “smart” circuitry for determining the status of the “smart” battery; and
   an electronic battery label for displaying the status of a “smart” battery, wherein the electronic battery label comprises:
      an e-paper display;
      means for mounting the e-paper display to the “smart” battery; and
      connection means for electrically connecting the e-paper display to the “smart” circuitry of the “smart” battery; and
displaying the status of the “smart” battery on the e-paper display.

### REFERENCE TO PENDING PRIOR PATENT APPLICATION

This patent application claims benefit of pending prior U.S. Provisional Patent Application Ser. No. 61/003,327, filed Nov. 16, 2007 by Michael E. Grosberg et al. for RECHARGEABLE “SMART” BATTERY WITH CYCLE STATUS INDICATOR FOR USE IN MOBILE HANDHELD ELECTRICAL DEVICE (Attorney's Docket No. GLOBALTECH-3 PROV), which patent application is hereby incorporated herein by reference.

### FIELD OF THE INVENTION

This invention relates to batteries in general, and more particularly to rechargeable “smart” batteries of the type which incorporate circuitry for monitoring battery status.

### BACKGROUND OF THE INVENTION

Many mobile electrical devices utilize rechargeable batteries. By way of example but not limitation, electric cars, mobile computers, laptop computers, portable barcode scanners, wireless telephones, military and public security radios, portable defibrillators, iPods, personal digital assistants (PDAs), etc. all use rechargeable batteries. Rechargeable batteries are particularly important in handheld electrical devices, where the mobile power supply must generally be small, lightweight and meet a particular housing configuration (i.e., “form factor”). In most cases, the rechargeable batteries on these devices are charged-discharged-recharged, etc. on a repetitive basis as the electrical devices go through their normal use. This process of charge-discharge-recharge may sometimes be referred to as the duty cycle of the battery.

Most rechargeable batteries have a service life which is a function of the number of duty cycles that the battery has experienced: the higher the number of duty cycles experienced, the shorter the remaining life of the battery. Furthermore, most rechargeable batteries also have a charge storage capacity which is a function of the number of duty cycles that the battery has experienced: the higher the number of duty cycles, the lower the maximum charge capacity of the battery, even after a “full” recharge.

As a result, with rechargeable batteries, it can be important to know the number of duty cycles that the battery has experienced. It can also be important to know the current charge storage capacity of the battery. For this reason, so-called “smart” batteries have been developed: these smart batteries incorporate circuitry for monitoring various aspects of the current status of the battery. Such status information may include the number of duty cycles that the battery has experienced, its current charge storage capacity, etc.

Some of the electrical devices utilizing rechargeable smart batteries include circuitry for retrieving and displaying some or all of the information regarding the current battery status. For example, portable barcode readers, security radios, laptop computers and wireless telephones all typically include circuitry for reading and displaying the current battery charge. However, relatively few electrical devices include circuitry for retrieving and displaying the number of duty cycles experienced by the battery.

Furthermore, even where the electrical devices include such circuitry, the battery must be mounted in the device, and the device must be powered on, in order for the electrical device to display the duty cycle information to the user.

Additionally, some external battery chargers and/or expensive battery analyzing equipment possess the ability to retrieve and display some or all of the information regarding battery status. However, these devices generally require that the battery be mounted into the charger and/or analyzer cradle, and the charger or analyzer turned on in order to display the duty cycle information to the user.

Unfortunately, in many situations, a user may need to “grab” a fresh battery “on the run” from a supply of recharged batteries before heading out into the field for use, e.g., a police officer may need to grab a fresh battery at the police station before heading out on patrol. In these circumstances, there is seldom time to mount the battery in the electrical device, power on the device, and then check the duty cycle information before leaving a base station. This is particularly true where the electrical device is a handheld electrical device such as a military or public security radio, portable defibrillator or other emergency-response device. As a result, the user may end up with a battery having a high duty cycle count and, therefore, a reduced charge storage capacity even when the battery is freshly recharged. This can pose life-threatening consequences. This is particularly true where the user will be in the field for several days at a location where charge capacity is extremely important and the supply of fresh batteries is non-existent (e.g., military applications).

There are many other situations in which it can be important for a user to know battery status quickly and conveniently, e.g., “on the run”. By way of example but not limitation, consider a business that has thousands of locations or trucks, with thousands of batteries in use at each location. These batteries are relied on to maximize worker productivity, and to enable the flow of important data and voice information. When batteries do not last a full workshift, the cost to the business can be substantial, e.g., millions of dollars in lost productivity and possible loss of the customer. In these cases, users of these batteries, who are spread across the business, require a fast and easy way (i.e., a visual indicator on the battery pack) to ensure they are using a battery with an adequate power capacity for the job. Such a feature would also enable these businesses to easily manage their supplies of batteries by enabling people with limited technical expertise, widespread throughout the organization, to take a certain action based on the number of duty cycles they are able to easily read on each battery.

In U.S. Pat. No. 5,895,440, there is disclosed a rechargeable battery assembly which includes a cycle status indicator thereon. Unfortunately, this battery assembly is designed to use multi-element LED assemblies, or LCD assemblies, to display cycle status information to the user. While LEDs and LCDs may be acceptable on large rechargeable batteries of the type used in boats, motor homes, fork lifts, etc. (i.e., such as those discussed in U.S. Pat. No. 5,895,440), these LED and LCD displays are generally impractical for the compact rechargeable batteries typically utilized in small handheld devices (e.g., security radios, PDAs, portable barcode readers, etc.). This is because the compact rechargeable batteries typically utilized in such handheld devices frequently must fit within the casing of the electrical device, making a close sliding fit with the casing. In other words, the compact rechargeable batteries typically utilized in handheld electrical devices must meet a form factor which is dictated by the handheld device, and this form factor generally has very strict tolerances which makes the use of LED and LCD displays impossible.

In addition, and significantly, with the battery construction of U.S. Pat. No. 5,895,440, the user must physically “turn on” the LED/LCD display in order to see the current status of the battery. This is time-consuming and inconvenient, particularly where the user may be rushing out into the field.

Furthermore, the power capacity of batteries used in small handheld devices is limited, and the LED/LCD displays taught in U.S. Pat. No. 5,895,440 generally draw too much power to be practical for such batteries.

Furthermore, and significantly, LED and LCD displays are generally fragile. When used in applications such as public safety, military or highly mobile businesses (e.g., delivery workers), LED and LCD displays are prone to breakage from dropping, shock and other environmental extremes which makes their use in these applications impractical.

### SUMMARY OF THE INVENTION

The present invention is intended to address the foregoing deficiencies of the prior art, by providing a new and improved rechargeable smart battery assembly which incorporates a cycle status indicator thereon and yet which is compact enough to fit within the casings of portable electrical devices, e.g., handheld electrical devices such as radios, barcode scanners, PDAs, etc.

In one preferred form of the invention, there is provided an electronic battery label for displaying the status of a “smart” battery, wherein the “smart” battery comprises “smart” circuitry for determining the status of the “smart” battery, the electronic battery label comprising:

an e-paper display;

means for mounting the e-paper display to the “smart” battery; and

connection means for electrically connecting the e-paper display to the “smart” circuitry of the “smart” battery.

In another preferred form of the invention, there is provided a “smart” battery assembly comprising:

a “smart” battery comprising “smart” circuitry for determining the status of the “smart” battery; and

an electronic battery label for displaying the status of a “smart” battery, wherein the electronic battery label comprises:
an e-paper display;
means for mounting the e-paper display to the “smart” battery; and
connection means for electrically connecting the e-paper display to the “smart” circuitry of the “smart” battery.

In another preferred form of the invention, there is provided a method for displaying the status of a battery, the method comprising:

providing a “smart” battery assembly comprising:
a “smart” battery comprising “smart” circuitry for determining the status of the “smart” battery; and
an electronic battery label for displaying the status of a “smart” battery, wherein the electronic battery label comprises:
   an e-paper display;
   means for mounting the e-paper display to the “smart” battery; and
   connection means for electrically connecting the e-paper display to the “smart” circuitry of the “smart” battery; and

displaying the status of the “smart” battery on the e-paper display.

### BRIEF DESCRIPTION OF THE DRAWINGS

These and other objects and features of the present invention will be more fully disclosed or rendered obvious by the following detailed description of the invention, which is to be read in conjunction with the attached drawings wherein like numbers refer to like parts, and further wherein:

FIGS. 1-3 are schematic views showing one preferred form of the novel rechargeable smart battery assembly of the present invention.

### DETAILED DESCRIPTION OF THE INVENTION

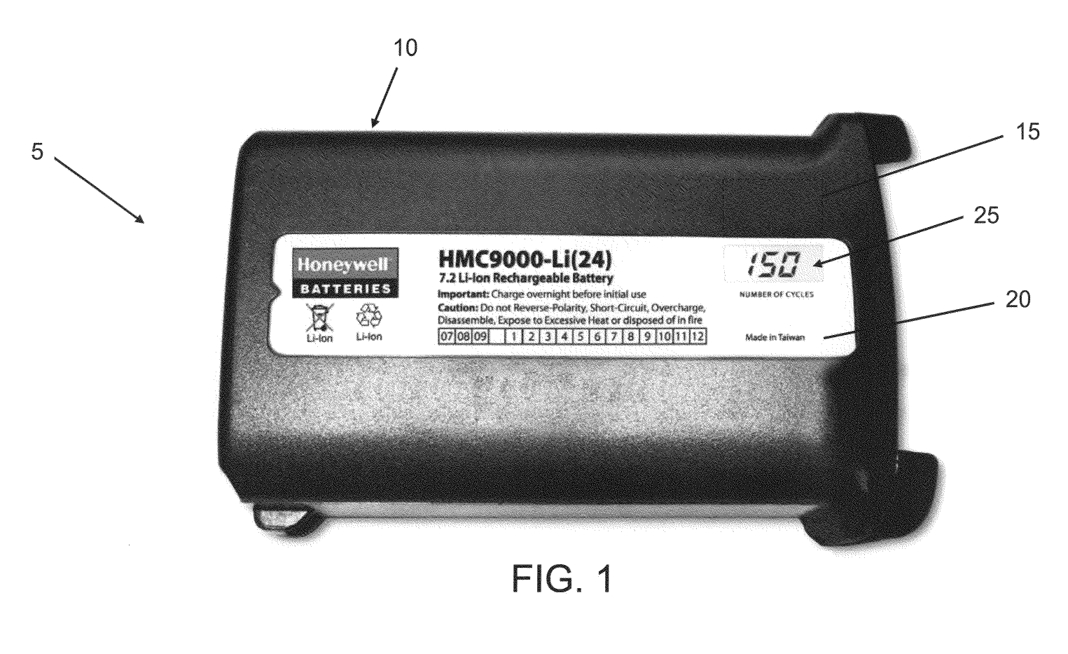

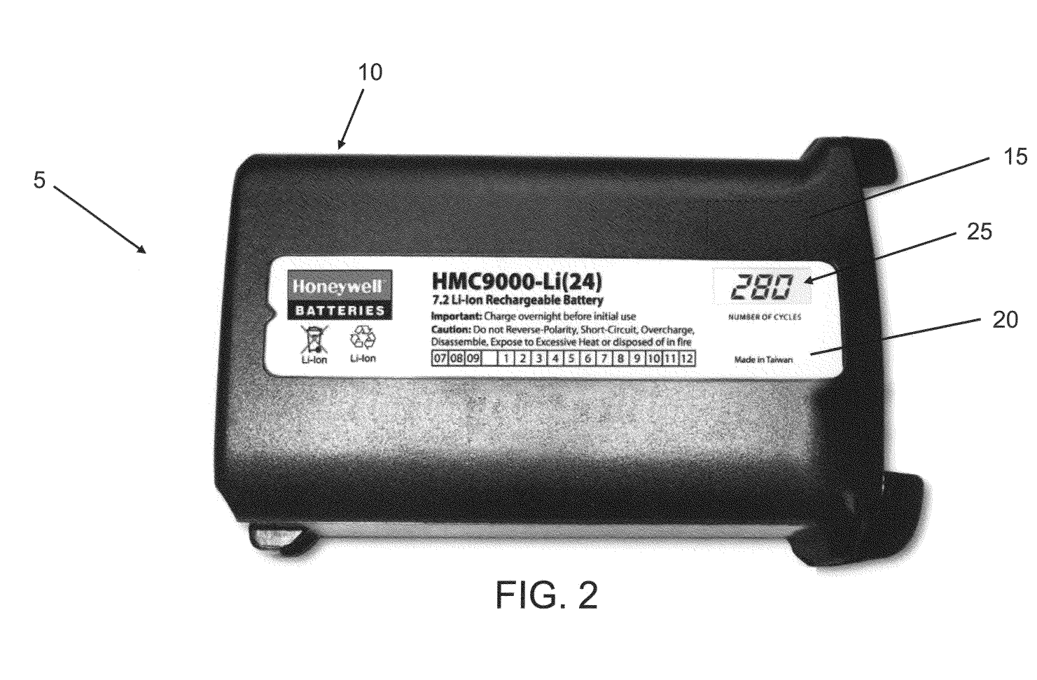

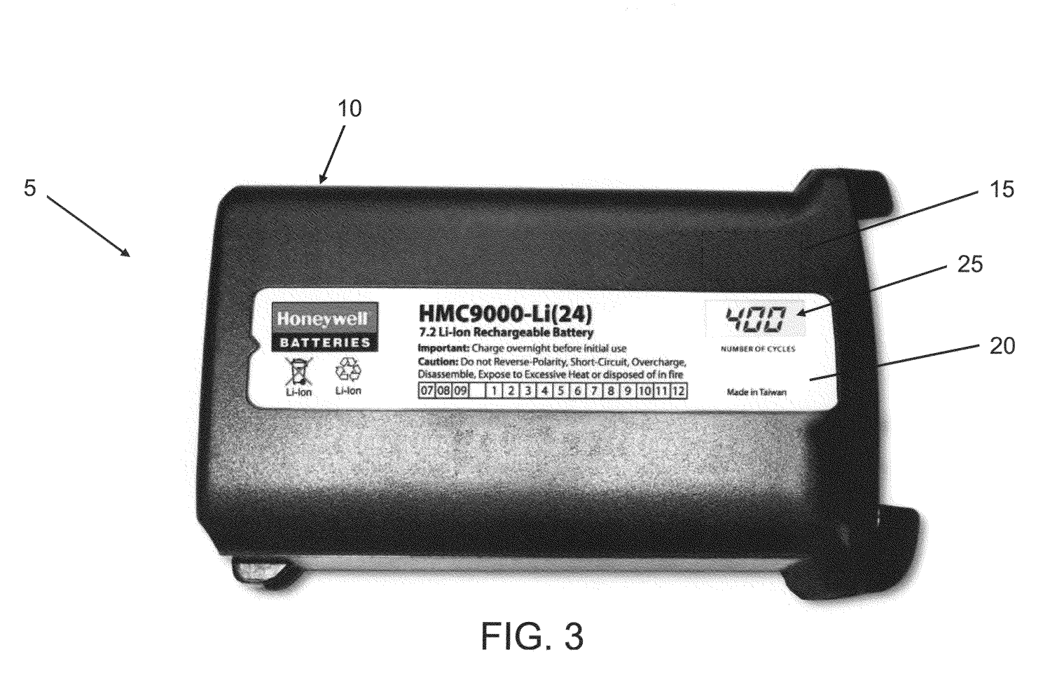

Looking now at FIGS. 1-3, there is shown a new rechargeable smart battery assembly 5 which incorporates a cycle status indicator thereon and yet which is compact enough to fit within the casings of portable electrical devices, e.g., handheld electrical devices such as radios, barcode scanners, PDAs, etc. In essence, the new smart battery assembly of the present invention provides a cycle status indicator which is so thin that it can be incorporated into the battery label itself. Thus, the smart battery assembly of the present invention has essentially the same dimensions as the battery alone, yet provides a visual cycle status indicator thereon.

More particularly, and still looking now at FIGS. 1-3, smart battery assembly 5 generally comprises a battery 10 which includes “smart” circuitry 15 therein for monitoring battery status (i.e., experienced duty cycles, as well as any other status information desired). Smart battery assembly 5 also includes a battery label 20 affixed to the exterior of the battery, and an ultra thin electronic status indicator 25 for visually displaying information provided by smart circuitry 15.

In one preferred form of the present invention, battery 10 comprises a Lithium ion/Lithium polymer battery pack of the sort available from Global Technology Systems, Inc. of Framingham, Mass.; “smart” circuitry 15 includes appropriate algorithms and circuitry of the sort well known in the art to measure the number of duty cycles stored in a battery through, among other things, the number of charge-discharge-recharge cycles the battery pack has experienced since its initial use, the length of charge, etc.; and ultra thin electronic status indicator 25 comprises the new, ultra thin electronic ink display technology of the sort commercially available from E Ink of Cambridge, Mass. or Xerox of Palo Alto, Calif. This new electronic ink display technology is sometimes referred to as “electronic paper” or “e-paper”.

As noted in Wikipedia, “[e]lectronic paper, also called e-paper, is a display technology designed to mimic the appearance of ordinary ink on paper. Unlike a conventional flat panel display, which uses a backlight to illuminate its pixels, electronic paper reflects light like ordinary paper and is capable of holding text and images indefinitely without drawing electricity, while allowing the image to be changed later. Unlike tradition displays e-paper can be crumpled or bent like traditional paper. One important feature needed is that the pixels be image stable, or bistable, so that the state of each pixel can be maintained without a constant supply of power.”

Significantly, electronic status indicator 25 of smart battery assembly 5 is so thin that it can effectively constitute, or be integrated into, a label, e.g., battery label 20.

Thus, in one form of the invention, battery label 20 and electronic status indicator 25 are essentially combined into a single electronic label which may be used to display various aspects of battery status, e.g., experienced duty cycles, current battery capacity, current battery capacity as a percentage of rated capacity, diagnostic information, remaining “lifetime” on the battery, etc., as well as other information of the sort normally placed on a standard battery label, e.g., safety information, certifications, manufacturer, model number, lot number, etc. In other words, in this form of the invention, the aforementioned e-paper technology is utilized to form a novel electronic label which includes all of the information normally contained on a standard battery label, as well as the information contained on electronic status indicator 25. On account of this construction, the new electronic label is completely compatible with applications where the battery must fit in a tight casing enclosure in the handheld electrical device, with minimal or no support from the electronic circuitry of the handheld electrical device itself.

Advantageously, and significantly, this new electronic ink display technology used to form the electronic label only draws power when it has its display “set”, which typically only takes about a second or so, and thereafter stays “on” without drawing any further power. Thus, with the new electronic label of the present invention, power is only required for a second or so while the display is updated (e.g., with cycle count, etc.) and thereafter the display is permanently “on”, ready to be read at a glance by a user. Significantly, where the battery status relates only to duty cycle count, the electronic label can be set at the time the battery is being recharged, at which time external power is available. Where the battery status relates to changing information (e.g., the current charge capacity of the battery), the electronic label needs to be briefly refreshed from time-to-time, but such refreshes are quite brief, e.g., taking only a second or two. Thus, the electronic label of the smart battery assembly is able, using no or nominal amounts of battery power, to continuously display the number of duty cycles that the battery has experienced and its charge capacity, among other things. Furthermore, the electronic label of the smart battery assembly does not “erase itself” if it should be without power.

In one preferred form of the present invention, the display is updated periodically, by integrating a timer and updating the display at every X interval. This approach effectively gives the user “up-to-date” battery status information during the entire discharge cycle of the battery.

Smart battery assembly 5 of the present invention offers many advantages. First, the electronic label is ultra thin, so it can be incorporated into existing portable battery designs, even where the battery is small and must fit into a tight casing. Second, the electronic label draws little power, so it can be periodically updated with current status information. Third, due to its construction, the electronic label is “on” all of the time, and it is always readable “at a glance”, without requiring the battery to be loaded into its host electrical device (or a charger or analyzer) and the host electrical device (or charger or analyzer) turned on. Fourth, the electronic labels are rugged and can withstand multiple drops, shock or environmental extremes, thereby making them ideal for field applications such as military radios, hand-held scanners, etc. Furthermore, since the electronic label can be in the form of a sealed adhesive assembly applied to the outside of the battery pack, the battery pack itself can be sealed so as to prevent water and other contaminants from entering the battery pack. This is in marked contrast to LED and LCD displays, which are generally exposed to the environment or require that the battery pack itself be exposed to the environment.

### MODIFICATIONS

While the present invention has been described in terms of certain exemplary preferred embodiments, it will be readily understood and appreciated by those skilled in the art that it is not so limited, and that many additions, deletions and modifications may be made to the preferred embodiments discussed herein without departing from the scope of the invention.

What is claimed is:

1. An electronic battery label for displaying the status of a “smart” battery, wherein the “smart” battery comprises “smart” circuitry for determining the status of the “smart” battery, the electronic battery label comprising:
an e-paper display;
means for mounting the e-paper display to the “smart” battery; and
connection means for electrically connecting the e-paper display to the “smart” circuitry of the “smart” battery.

2. A “smart” battery assembly comprising:
a “smart” battery comprising “smart” circuitry for determining the status of the “smart” battery; and
an electronic battery label for displaying the status of a “smart” battery, wherein the electronic battery label comprises:
an e-paper display;
means for mounting the e-paper display to the “smart” battery; and
connection means for electrically connecting the e-paper display to the “smart” circuitry of the “smart” battery.

3. A method for displaying the status of a battery, the method comprising:
providing a “smart” battery assembly comprising:
a “smart” battery comprising “smart” circuitry for determining the status of the “smart” battery; and
an electronic battery label for displaying the status of a “smart” battery, wherein the electronic battery label comprises:
an e-paper display;
means for mounting the e-paper display to the “smart” battery; and
connection means for electrically connecting the e-paper display to the “smart” circuitry of the “smart” battery; and
displaying the status of the “smart” battery on the e-paper display.
